(19) United States
(12) Patent Application Publication
(10) Pub. No.: US 2024/0170842 A1
(43) Pub. Date: May 23, 2024

(54) PHASE SHIFT AMOUNT ADJUSTMENT DEVICE AND PHASE SHIFT AMOUNT ADJUSTMENT METHOD

(71) Applicant: Fujitsu Limited, Kawasaki-shi (JP)

(72) Inventor: Masafumi TSUTSUI, Kawasaki (JP)

(73) Assignee: Fujitsu Limited, Kawasaki-shi (JP)

(21) Appl. No.: 18/466,909

(22) Filed: Sep. 14, 2023

(30) Foreign Application Priority Data
Nov. 22, 2022 (JP) 2022-186179

(51) Int. Cl. H01Q 3/36; H03H 17/08

(52) U.S. Cl. CPC H01Q 3/36; H03H 17/08

(57) ABSTRACT

A phase shift amount adjustment device includes a memory and a processor to obtain reception power at a reception device that receives first and second signals from a transmission device that has first and second antennas to transmit the first and second signals whose phase shift amounts are adjusted by first and second phase shifters, respectively; store, in the memory, table data representing characteristics of amplitudes of the first and second signals with respect to change in the phase shift amounts of the phase shifters, respectively; calculate a squared value of a sum of first and second amplitudes of the first and second signals in first and second phase shift amounts of the phase shifters obtained from the table data; and adjust the first and second phase shift amounts so as to maximize an evaluation value obtained by dividing the reception power divided by the squared value.

### CROSS-REFERENCE TO RELATED APPLICATIONS

The present application is based upon and claims the benefit of priority of Japanese Patent Application No. 2022-186179 filed on Nov. 22, 2022, the entire contents of which are hereby incorporated by reference.

### FIELD

The present disclosure relates to a phase shift amount adjustment device and a phase shift amount adjustment method.

### BACKGROUND

Conventionally, there have been antenna devices that include multiple unit elements in a predetermined arrangement. Each of the multiple unit elements includes a signal transmission/reception unit configured to execute transmission of a transmission signal to be transmitted and reception of a reception signal to be received, or either one of transmission or reception; and an amplitude/phase adjustment unit configured to adjust the amplitude and phase of the transmission signal to be transmitted or the reception signal to be received according to control amounts for the amplitude and phase. The antenna device includes a signal measurement unit configured to measure the transmission signal that is transmitted with the adjusted amplitude and phase, and the reception signal that is received with the adjusted amplitude and phase, or either one of these signals; and a correction value calculation unit configured to calculate, based on the measured transmission signal and reception signal or either one of the signals, a correction value indicating a value of correction to be executed on a control amount in order to impart a desired control amount to the transmitted transmission signal and adjusted reception signal or either one of the signals (see, for example, Patent Document 1).

### RELATED ART DOCUMENTS

### Patent Documents

[Patent Document 1] Japanese Laid-Open Patent Application No. 2004-289730

Meanwhile, conventional antenna devices do not take into account power obtained based on characteristics of an actual output signal with respect to change in the phase shift amount of a phase shifter; therefore, sufficient accuracy is not obtained when adjusting the phase shift amount.

### SUMMARY

According to an embodiment in the present disclosure, a phase shift amount adjustment device includes a memory and a processor configured to obtain reception power at a reception device that receives a first signal and a second signal from a transmission device that has a first antenna to transmit the first signal whose phase shift amount is adjusted by a first phase shifter, and a second antenna to transmit the second signal whose phase shift amount is adjusted by a second phase shifter; store, in the memory, table data representing a characteristic of an amplitude of the first signal with respect to change in the phase shift amount of the first phase shifter, and a characteristic of an amplitude of the second signal with respect to change in the phase shift amount of the second phase shifter; calculate a squared value of a sum of a first amplitude of the first signal in a first phase shift amount of the first phase shifter obtained from the table data and a second amplitude of the second signal in a second phase shift amount of the second phase shifter obtained from the table data; and adjust the first phase shift amount and the second phase shift amount so as to maximize an evaluation value obtained by dividing the reception power by the squared value.

The object and advantages in the embodiment will be realized and attained by means of the elements and combinations particularly pointed out in the claims. It is to be understood that both the foregoing general description and the following detailed description are exemplary and explanatory and are not restrictive of the invention as claimed.

### BRIEF DESCRIPTION OF DRAWINGS

FIG. 1 is a diagram illustrating an example of a configuration of a phase shift amount adjustment device 100 and communication devices 10 and 20 according to an embodiment;

FIG. 2A is a diagram illustrating an example of a relationship between change in the phase shift amount of a phase shifter 13 and the reception power of the communication device 20;

FIG. 2B is a diagram illustrating an example of a characteristic of the amplitude of an output signal with respect to a phase shift amount φ₂ of the phase shifter 13;

FIG. 3 is a flow chart illustrating an example of a process of a phase shift amount adjustment method executed by the phase shift amount adjustment device 100; and

FIG. 4 is a diagram illustrating an example of a hardware configuration of the phase shift amount adjustment device 100.

### DESCRIPTION OF EMBODIMENTS

In the following, embodiments to which a phase shift amount adjustment device and a phase shift amount adjustment method according to the present disclosure are applied will be described. According to an embodiment, a phase shift amount adjustment device and a phase shift amount adjustment method that can adjust the phase shift amount with high accuracy are provided.

### Embodiments

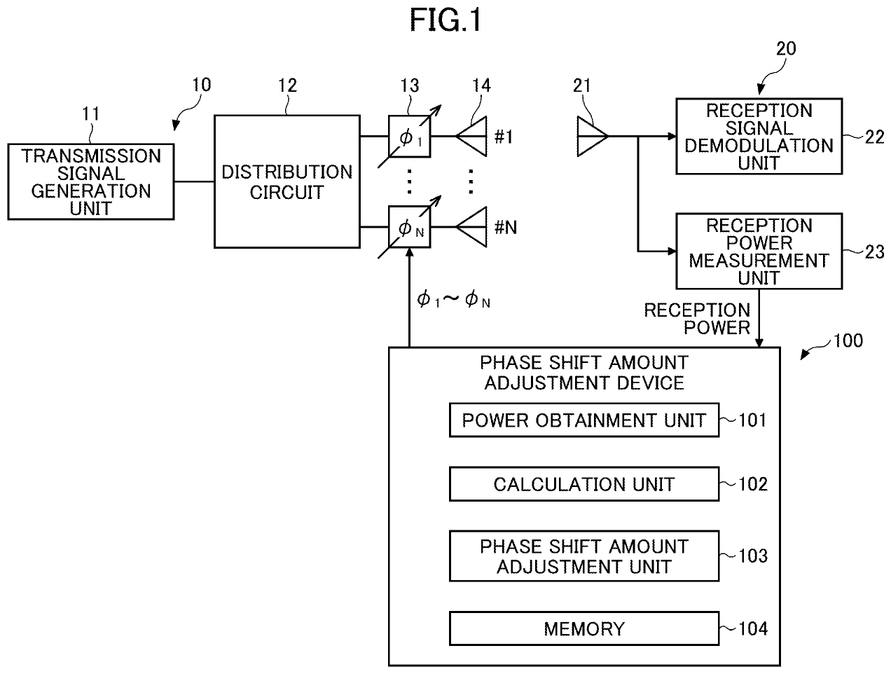

FIG. 1 is a diagram illustrating an example of a configuration of a phase shift amount adjustment device 100 and communication devices 10 and 20 according to an embodiment. The communication device 10 is an example of a transmission device, and the communication device 20 is an example of a reception device. The communication device 10 is, for example, a base station, and is arranged at a fixed location. The communication device 20 is, for example, a base station or a mobile station, and is arranged at a fixed location in the case of being a base station. As an example, the communication devices 10 and 20 can transmit and receive radio waves corresponding to standards such as the fifth generation (5G) mobile communication system or the sixth generation (6G) mobile communication system. In the following, as an example, a form in which the communication devices 10 and 20 communicate with each other by radio waves corresponding to the standards of 5G will be described.

### Communication Device 10

The communication device 10 includes a transmission signal generation unit 11, a distribution circuit 12, N (N is an integer greater than or equal to 2) phase shifters 13, and N antennas 14. Here, although a form in which the communication device 10 is a base station will be described, the communication device 10 simply needs to be capable of transmitting a signal at least.

Any one of the N phase shifters 13 is an example of a first phase shifter, and any one of the others is an example of a second phase shifter. Among the N antennas 14, an antenna 14 connected to the phase shifter 13 as an example of the first phase shifter is an example of a first antenna. Among the N antennas 14, an antenna 14 connected to the phase shifter 13 as an example of the second phase shifter is an example of a second antenna.

The transmission signal generation unit 11 is a device that generates a transmission signal, modulates a carrier wave with a baseband signal, and outputs the modulated carrier wave as the transmission signal to the distribution circuit 12. The distribution circuit 12 is provided between the transmission signal generation unit 11 and the N phase shifters 13, to distribute and output the transmission signal input from the transmission signal generation unit 11 to the N phase shifters 13.

Each of the N phase shifters 13 is provided between the distribution circuit 12 and a corresponding one of the N antennas 14, to shift the phase of a corresponding one of the N transmission signals input from the distribution circuit 12 by a phase shift amount of φ₁ to φ_{N}, and output the shifted signal to the corresponding one of the N antennas 14. The phase shift amount of the phase shifter 13 is an amount by which the phase of the input signal of the phase shifter 13 is shifted, and the phase of the output signal of the phase shifter 13 is shifted by the phase shift amount with respect to the input signal. The phase shift amount of each of the phase shifters 13 is set by the phase shift amount adjustment device 100.

Note that in order to adjust the phase shift amount of each of the phase shifters 13, the phase shift amount adjustment device 100 may be connected to the phase shifters 13 via a cable or the like so as to be capable of data communication, or may be configured to be capable of wireless communication with the phase shifters 13. The wireless communication may be communication based on the standards of 5G, or may be communication based on, for example, a wireless LAN (Local Area Network), BLE (registered trade mark), or a fourth generation (4G) mobile communication system.

The N antennas 14 are connected to the output sides of the respective N phase shifters 13, and transmit the transmission signals having the phases shifted by the respectively N phase shifters 13. The transmission signals transmitted from the N antennas 14 form one or more beams by beamforming. Here, as an example, a case of forming one beam will be described. The beam obtained by beamforming is directed at the antenna 21 of the communication device 20.

### Communication Device 20

The communication device 20 includes an antenna 21, a reception signal demodulation unit 22, and a reception power measurement unit 23. Here, although a form in which the communication device 20 is a base station arranged at a fixed location or a mobile station will be described, the communication device 20 simply needs to be capable of, at least, receiving a signal transmitted from the communication device 10.

The antenna 21 is connected to the reception signal demodulation unit 22 and the reception power measurement unit 23, and receives a transmission signal transmitted from the communication device 10. The reception signal demodulation unit 22 is a demodulator that demodulates the transmission signal received by the antenna 21 to extract data. The reception signal demodulation unit 22 outputs the data extracted from the transmission signal to an information processing device (not illustrated) or the like. The reception power measurement unit 23 measures the power (reception power) of the transmission signal received by the antenna 21. The reception power measurement unit 23 simply needs to be a device that is capable of measuring the reception power, and for example, a radio frequency (RF) measuring device or the like can be used.

### Phase Shift Amount Adjustment Device 100

The phase shift amount adjustment device 100 includes a power obtainment unit 101, a calculation unit 102, a phase shift amount adjustment unit 103, and a memory 104. The memory 104 is an example of a memory. A method executed by the phase shift amount adjustment device 100 to adjust the phase shift amounts φ₁ to φ_{N} of the N phase shifters 13 is the phase shift amount adjustment method of the embodiment.

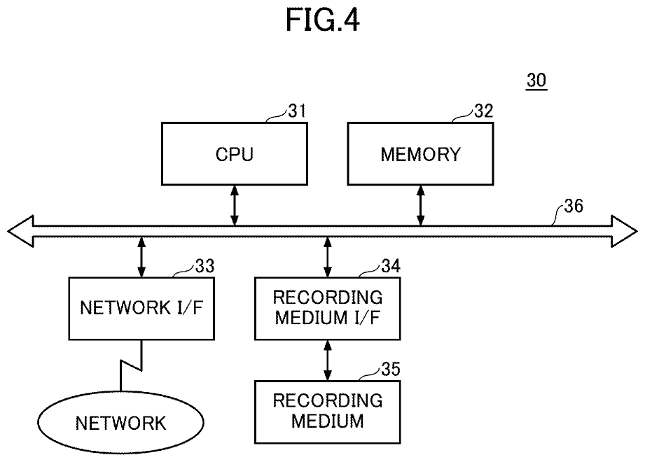

The phase shift amount adjustment device 100 is implemented by a computer that includes a central processing unit (CPU), a random access memory (RAM), a read-only memory (ROM), an input/output interface, an internal bus, and the like. Such a hardware configuration of the phase shift amount adjustment device 100 will be described later with reference to FIG. 4.

The power obtainment unit 101, the calculation unit 102, and the phase shift amount adjustment unit 103 represent functions of a program executed by the phase shift amount adjustment device 100 as functional blocks. In addition, the memory 104 is a functional representation of the memory of the phase shift amount adjustment device 100.

Based on the reception power measured by the reception power measurement unit 23 of the communication device 20, the phase shift amount adjustment device 100 adjusts the phase shift amounts φ₁ to φ_{N} of the N phase shifters 13 of the communication device 10 so as to maximize the reception power at the antenna 21. The phase shift amount adjustment device 100 may be provided on the communication device 10 side, may be provided on the communication device 20 side, or may be provided at a third location different from the locations of the communication devices 10 and 20.

The phase shift amount adjustment device 100 may be connected to the reception power measurement unit 23 via a cable or the like to be capable of data communication, or may be configured to be capable of wireless communication with the reception power measurement unit 23. The wireless communication may be communication compliant with the standards of 5G, or may be communication compliant with, for example, a wireless local area network (LAN), BLE (registered trade mark), or the fourth generation (4G) mobile communication system.

### Power Obtainment Unit 101

The power obtainment unit 101 obtains reception power at the communication device 20 that receives the N transmission signals from the communication device 10 that has the N antennas 14 to transmit the transmission signals having the phase shift amounts φ₁ to φ_{N} adjusted by the N phase shifters 13.

In other words, the power obtainment unit 101 obtains reception power at the communication device 20 that receives a transmission signal (first signal) and a transmission signal (second signal) from the communication device 10 that has an antenna 14 (first antenna) to transmit a transmission signal (first signal) whose phase shift amount is adjusted by a phase shifter 13 (first phase shifter), and an antenna 14 (second antenna) to transmit a transmission signal (second signal) whose phase shift amount is adjusted by a phase shifter 13 (second phase shifter).

### Calculation Unit 102

The calculation unit 102 calculates a squared value of the sum of the amplitudes of the N transmission signals in the N phase shift amounts of the N phase shifters 13 obtained from table data stored in the memory 104. The amplitudes of the N transmission signals are the amplitudes of the output signals of the N phase shifters 13. Note that the calculation method of the squared value will be described later.

In other words, the calculation unit 102 calculates a squared value of the sum of the first amplitude of the transmission signal (first signal) in the phase shift amount (first phase shift amount) of a phase shifter 13 (first phase shifter) obtained from the table data, and the second amplitude of the transmission signal (second signal) in the phase shift amount (second phase shift amount) of another phase shifter 13 (second phase shifter) obtained from the table data, where the table data is stored in the memory 104.

### Phase Shift Amount Adjustment Unit 103

The phase shift amount adjustment unit 103 adjusts the N phase shift amounts φ₁ to φ_{N} of the N phase shifters 13, so as to maximize an evaluation value obtained by dividing the reception power obtained by the power obtainment unit 101 by the squared value calculated by the calculation unit 102. Note that the calculation method of evaluation value will be described later.

In other words, the phase shift amount adjustment unit 103 adjusts the phase shift amount (first phase shift amount) and the phase shift amount (second phase shift amount), so as to maximize the evaluation value obtained by dividing the reception power obtained by the power obtainment unit 101 by the squared value calculated by the calculation unit 102.

### Memory 104

The memory 104 stores the table data representing a characteristic of the amplitude of the transmission signal (output signal of the phase shifter 13) with respect to change in the phase shift amount in each of the N phase shifters 13. The memory 104 stores table data representing characteristics of N amplitudes for the N phase shifters 13.

In other words, the memory 104 stores table data representing a characteristic of the amplitude of the transmission signal (first signal) with respect to change in the phase shift amount of the phase shifter 13 (first phase shifter), and a characteristic of the amplitude of the transmission signal (second signal) with respect to change in the phase shift amount of the phase shifter 13 (second phase shifter). The table data stored in the memory 104 includes first table data for the phase shifter 13 (first phase shifter) and second table data for the phase shifter 13 (second phase shifter). The first table data represents a first characteristic of the amplitude of the transmission signal (first signal) with respect to the phase shift amount in the phase shifter 13 (first phase shifter). The second table data represents a second characteristic of the amplitude of the transmission signal (second signal) with respect to the phase shift amount in the phase shifter 13 (second phase shifter).

Note that the table data stored in the memory 104 may be table data representing one characteristic common to the N phase shifters 13. In this case, with respect to the one characteristic represented in the table data stored in the memory 104, the amplitude corresponding to the phase shift amount of the N phase shifters 13 is extracted.

In other words, the common table data is table data representing a characteristic of the amplitudes of the transmission signal (first signal) and the transmission signal (second signal) with respect to the phase shift amount in the phase shifter 13 (first phase shifter) and the phase shifter 13 (second phase shifter).

### Characteristic of Amplitude of Output Signal with Respect to Change in Shase shift Amount φ of Phase Shifter 13

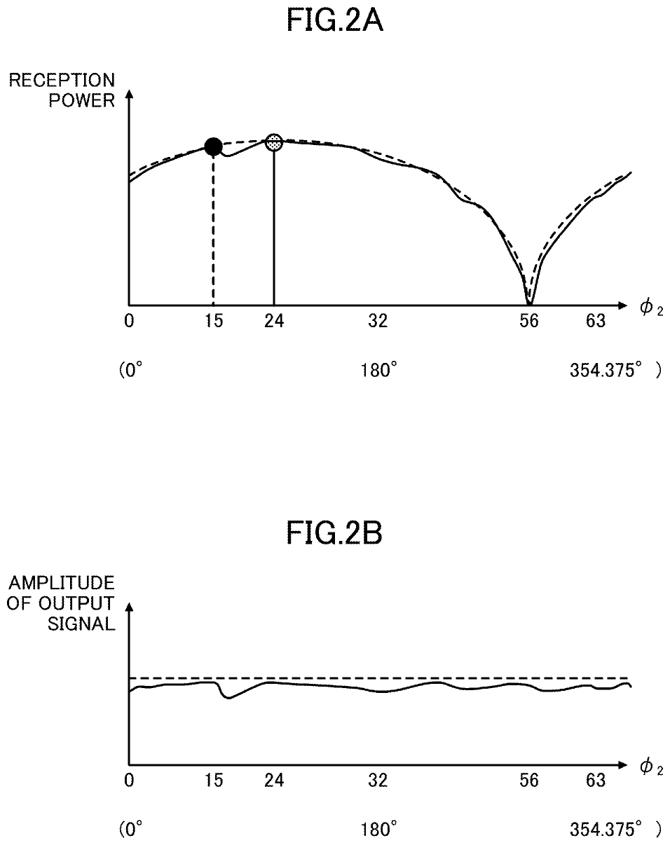

FIG. 2A is a diagram illustrating an example of a relationship between change in the phase shift amount of a phase shifter 13 and the reception power of the communication device 20. For example, in FIG. 1, assume that the number of phase shifters 13 is two (N=2), and the phase shift amount φ₁ of the first (#1) phase shifter 13 is fixed; in this case, when the phase shift amount φ₂ of the second (#2) phase shifter 13 is changed, the reception power of the communication device 20 changes as illustrated in FIG. 2A. In FIG. 2A, the horizontal axis represents the phase shift amount φ₂ of the second (#2) phase shifter 13, and the vertical axis represents the reception power of the communication device 20. In FIG. 2A, the phase shift amount (0 degrees to 360 degrees) on the horizontal axis is represented in six bits (64 gradations from 0 to 63) . The Oth phase shift amount is 0 degrees, the 32nd phase shift amount is 180 degrees, and the 63rd phase shift amount is 354.375 degrees.

Meanwhile, the phase shifters 13 have individual differences, and there is an error or a variation in the amplitude of an output signal with respect to the phase shift amount of each phase shifter 13. For example, in the case where the phase shift amount φ₁ of the first (#1) phase shifter 13 is fixed, and the phase shift amount φ₂ of the second (#2) phase shifter 13 is changed, assume that the reception power of the communication device 20 changes as illustrated by a solid line in FIG. 2A. Note that the reason why the reception power is zero at the 56th phase shift amount φ₂ is that the phase shift amount φ₁ and the phase shift amount φ₂ are opposite phases at the 56th phase shift amount φ₂.

In FIG. 2A, the characteristic of an ideal reception power of the communication device 20 with respect to the change in the phase shift amount φ₂ is illustrated by a broken line. The ideal reception power characteristic is a characteristic obtained from theoretical values. The characteristic of the actual reception power of the communication device 20 illustrated by the solid line deviates from the ideal characteristic illustrated by the broken line, and the reception power becomes maximum at the 24th phase shift amount φ₂; however, for example, as the reception power is lower than the ideal characteristic between the 15th phase shift amount φ₂ and the 24th phaseshift amount φ₂, it is assumed here that the reception power at the 15th phase shift amount φ₂ is a maximal value.

In such a case, if the phase shift amount φ₂ is sequentially changed from the 0th phase shift amount to search for the phase shift amount φ₂ that maximizes the reception power, the maximal value of the reception power at the 15th phase shift amount φ₂ may be determined as the maximum value before reaching the 24th phase shift amount φ₂ that maximizes the reception power. In other words, there is a likelihood that a local solution of the 15th phase shift amount φ₂ is erroneously obtained.

The reason why the actual characteristic (solid line) of the reception power of the communication device 20 deviates from the ideal characteristic (broken line) in this way is that an error or a variation occurs in the amplitude of the output signal with respect to the phase shift amount of the phase shifter 13 due to the individual difference of the phase shifter 13, variation in the characteristics of the circuits between the distribution circuit 12 and the antenna 14, and the like.

FIG. 2B is a diagram illustrating an

example of a characteristic of the amplitude of an output signal with respect to a phase shift amount φ₂ of the phase shifter 13. In FIG. 2B, an example of the characteristic of the amplitude of an actual output signal from the phase shifter 13 with respect to the change in the phase shift amount φ₂ is illustrated by a solid line. In addition, an ideal characteristic of the amplitude of the output signal of the phase shifter 13 with respect to change in the phase shift amount φ₂ is illustrated by a broken line. The characteristic of the amplitude of the ideal output signal is a characteristic obtained from theoretical values.

As illustrated in FIG. 2B, the ideal characteristic of the amplitude of the output signal of the phase shifter 13 with respect to change in the phase shift amount φ₂ (broken line) is constant with respect to the change in the phase shift amount φ₂. However, in practice, as there is an error, a variation, or the like, the amplitude of the actual output signal of the phase shifter 13 fluctuates with respect to the change in the phase shift amount φ₂ as illustrated by the solid line, and is lower than the values in the ideal characteristic. The reason why the actual amplitude is lower than the ideal amplitude in this way is that a loss occurs in the output of the actual phase shifter 13.

As an example, as illustrated in FIG. 2B by the solid line, if a minimal value of the amplitude of the output signal exists between the 15th phase shift amount φ₂ and the 24th phase shift amount φ₂, as illustrated by the solid line in FIG. 2A, a minimal value occurs also in the reception power between the 15th phase shift amount φ₂ and the 24th phase shift amount φ₂, and an event of erroneously obtaining a local solution may occur.

The phase shift amount adjustment device 100 according to the embodiment suppresses such erroneous obtainment of a local solution, to be capable of highly accurately adjusting the phase shift amounts φ₁ to φ_{N} of the N phase shifters 13 to phase shift amounts that maximize the reception power of the communication device 20. In the following, a specific method of adjusting the N phase shift amounts φ₁ to φ_{N} will be described. The method of adjusting the phase shift amounts φ₁ to φ_{N} includes obtainment of the reception power of the communication device 20 as the reception device, use of the table data stored in the memory 104, calculation of the squared value, and calculation of the evaluation value. In the following, the table data stored in the memory 104, calculation of the squared value, and calculation of the evaluation value will be described.

### Table Data Stored in Memory 104

The table stored in the memory 104 includes actual characteristics of the amplitudes of signals output from the N phase shifters 13 with respect to changes in the N phase shift amounts φ₁ to φ_{N}, such as the actual characteristics of the amplitudes of the signals output from the phase shifter 13 with respect to changes in the phase shift amount φ₂ illustrated by the solid line in FIG. 2B. The characteristics of the amplitudes of the actual output signal with respect to the change in the phase shift amount in the phase shifter 13 may be measured in advance, for example, by an experiment or the like, and stored as the table data.

Note that for example, in the case where errors or variations in the characteristics of the amplitudes of the output signals with respect to changes in the phase shift amounts φ₁ to φ_{N} of the N phase shifters 13 are relatively small, the table data stored in the memory 104 may be table data representing one characteristic common to the N phase shifters 13. In addition, the N phase shifters 13 may be divided into several groups according to the errors, variations, or the like in the characteristics, and table data for each group may be stored in the memory 104.

### Calculation of Squared Value

The squared value is calculated by the calculation unit 102. Here, the amplitudes of the N transmission signals at the N phase shift amounts of the N phase shifters 13 obtained from the table data φ₁ to φ_{N} stored in the memory 104 are denoted as A (φ₁) to A(φ_{N}). The amplitudes of the N transmission signals are the amplitudes of the output signals of the N phase shifters 13.

The calculation unit 102 calculates a squared value S of the sum of the amplitudes A (φ₁) to A (φ_{N}) of the N transmission signals at the N phase shift amounts of the N phase shifters 13 obtained from the table data φ₁ to φ_{N} according to the following Formula (1):

S=|A(φ₁)+A(φ₂)+ . . . +A(φ_{N})|² (1)

In Formula (1), A(φ₁)+A (φ₂)+ . . . +A (φ_{N}) is obtained from the table data stored in the memory 104; therefore, S represents the total value of the amplitudes of the transmission signals actually received by the antenna 21 of the communication device 20 as the reception device. The amplitude corresponds to a voltage value; therefore, the squared value S obtained by Formula (1) represents an expected value expected as the reception power actually obtained by the antenna 21 of the communication device 20 as the reception device.

### Calculation of Evaluation Value

The phase shift amount adjustment unit 103 obtains an evaluation value E by dividing the reception power P obtained by the power obtainment unit 101 by the squared value S. The evaluation value E is obtained by the following Formula (2):

E=P/S (2)

The reception power P of the communication device 20 is divided by the squared value S as the expected value of the actual reception power of the communication device 20; therefore, the evaluation value E is a value obtained by normalizing the reception power P by the squared value S. The squared value S is a value corresponding to power; therefore, the evaluation value E obtained by dividing the reception power P by the squared value S is a value having no unit. However, the evaluation value E is a value obtained by normalizing the reception power P by the squared value S; therefore, it can be considered that the characteristic of the evaluation value E with respect to the N phase shift amounts corresponds to a characteristic obtained by correcting the characteristic (corresponding to the squared value S) illustrated by the solid line in FIG. 2A to the ideal reception power illustrated by the broken line (the shape of the change with respect to the phase shift amount is equivalent to the ideal characteristic).

Therefore, if the N phase shift amounts φ₁ to φ_{N} are adjusted so as to maximize the evaluation value E, the N phase shift amounts φ₁ to φ_{N} can be adjusted with high accuracy so that the communication device 20 can obtain the maximum reception power.

### Flow Chart

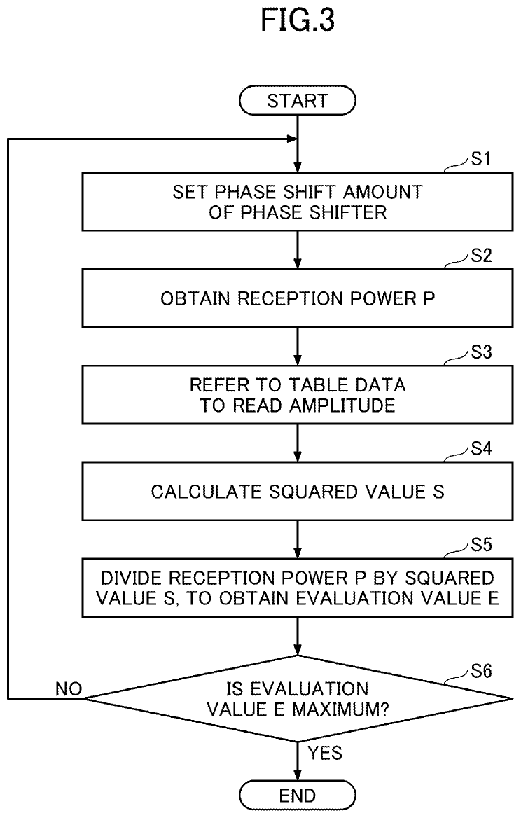

FIG. 3 is a flow chart illustrating an example of a process of a phase shift amount adjustment method executed by the phase shift amount adjustment device 100. The process illustrated in FIG. 3 is executed by the power obtainment unit 101, the calculation unit 102, and the phase shift amount adjustment unit 103 of the phase shift amount adjustment device 100.

Once the process starts, the phase shift amount adjustment unit 103 sets the phase shift amounts φ₁ to φ_{N} of the N phase shifters 13 (Step S1). Note that the phase shift amount adjustment device 100 repeatedly executes processing at Steps S1 to S6 in predetermined control periods; when executing processing at Step S1 in the first control period, the phase shift amounts φ₁ to φ_{N} may be set to initial values. The initial values may be set in advance for the phase shift amounts φ₁ to φ_{N.}

The power obtainment unit 101 obtains the reception power of the communication device 20 (Step S2). More specifically, the power obtainment unit 101 transmits transmission signals from the N antennas 14 of the communication device 10, and obtains the reception power at the communication device 20 from the reception power measurement unit 23, in a state where the phase shift amounts φ₁ to φ_{N} are individually adjusted in the N phase shifters 13.

The calculation unit 102 refers to the table data stored in the memory 104, to read the amplitudes A (φ₁) to A (φ_{N}) corresponding to the phase shift amounts φ₁ to φ_{N} set at Step S1 from the table data corresponding to the phase shifter 13 (Step S3).

The calculation unit 102 calculates the squared value S of the sum of the N amplitudes A (φ₁) to A (φ_{N}) read at Step S3 according to Formula (1) (Step S4).

The phase shift amount adjustment unit 103 divides the reception power P obtained at Step S2 by the squared value S calculated at Step S4 according to Formula (2), to obtain the evaluation value E (Step S5). The phase shift amount adjustment unit 103 stores the obtained evaluation value E in the memory 104.

The phase shift amount adjustment unit 103 determines whether the evaluation value E obtained at Step S5 is the maximum among the evaluation values E obtained up to then (Step S6). The phase shift amount adjustment unit 103 compares the evaluation value E previously stored in the memory 104 (evaluation value E obtained up to the previous control period) with the evaluation value E obtained in the current control period, to determine whether the evaluation value E obtained in the current control period is the maximum.

If it is determined that the evaluation value E is not the maximum (NO at Step S6), the phase shift amount adjustment unit 103 returns the flow to Step S1. As a result, the phase shift amount adjustment device 100 repeats execution of the processing at Steps S1 to S6.

On the other hand, if it is determined at Step S6 that the evaluation value E is the maximum YES at Step S6), the phase shift amount adjustment unit 103 ends the series of processing. The phase shift amount adjustment unit 103 sets the phase shift amounts φ₁ to φ_{N} that give the maximum evaluation value E to the respective N phase shifters 13.

Note that in order to ultimately obtain a global solution at Step S6, for example, a method called regula falsi may be executed, in which Steps S1 to S6 are repeated while increasing the phase shift amounts φ₁ to φ_{N} to drive them up to phase shift amounts at which the evaluation value E turns from increasing to decreasing, and then, while decreasing the phase shift amounts φ₁ to φ_{N} to drive them down to phase shift amounts at which the evaluation value E turns again from increasing to decreasing. In this way, the phase shift amounts φ₁ to φ_{N} that give the maximum evaluation value E may be obtained while sequentially updating the phase shift amounts φ₁ to φ_{N}. At this time, the phase shift amounts φ₁ to φ_{N} that give the maximum value of the evaluation value E can be efficiently found by setting the interval of increasing and decreasing the phase shift amounts φ₁ to φ_{N} to be greater at first, and then, to be smaller gradually.

### Hardware Configuration of Phase Shift Amount Adjustment Device 100

FIG. 4 is a diagram illustrating an example of a hardware configuration of the phase shift amount adjustment device 100. FIG. 4 illustrates a computer 30 that implements the phase shift amount adjustment device 100. The phase shift amount adjustment device 100 is implemented by a computer 30 that includes a CPU 31, a memory 32, a network I/F 33, a recording medium I/F 34, and a recording medium 35. In addition, the components are connected to each other via a bus 36.

Here, the CPU 31 manages overall control of the phase shift amount adjustment device 100. The memory 32 includes, for example, a ROM, a RAM, a flash ROM, and the like. Specifically, for example, the flash ROM or the ROM stores various programs, and the RAM is used as a work area of the CPU 31. The program stored in the memory 32 is loaded into the CPU 31 to cause the CPU 31 to execute coded processes.

The network I/F 33 is connected to a network through a communication line, and is connected to another computer via the network. The other computer may be a computer included in the communication device 10 or 20. In addition, the network I/F 33 serves as an interface between the network and the inside, and controls input and output of data with the other computer. The network I/F 33 is, for example, a modem or a LAN adapter.

The recording medium I/F 34 controls reading/writing on the recording medium 35 under control of the CPU 31. The recording medium I/F 34 is, for example, a disk drive, an SSD, a USB port, or the like. The recording medium 35 is a nonvolatile memory that stores information written under control of the recording medium I/F 34. The recording medium 35 is, for example, a disk, a semiconductor memory, a USB memory, or the like. The recording medium 35 may be removable from the phase shift amount adjustment device 100.

Note that the elements included in the phase shift amount adjustment device 100 may be implemented by causing the CPU 31 to execute a program stored in a storage area such as the memory 32 or the recording medium 35, or by the network I/F 33.

### Effects

The phase shift amount adjustment device 100 includes: the power obtainment unit 101 configured to obtain reception power P at the communication device 20 that receives a transmission signal (first signal) and a transmission signal (second signal) from the communication device 10 that has an antenna 14 (first antenna) to transmit a transmission signal (first signal) whose phase shift amount is adjusted by a phase shifter 13 (first phase shifter), and an antenna 14 (second antenna) to transmit a transmission signal (second signal) whose phase shift amount is adjusted by a phase shifter 13 (second phase shifter); the memory 104 configured to store table data representing a characteristic of the amplitude of the transmission signal (first signal) with respect to change in the phase shift amount of the phase shifter 13 (first phase shifter), and a characteristic of the amplitude of the transmission signal (second signal) with respect to change in the phase shift amount of the phase shifter 13 (second phase shifter); the calculation unit 102 configured to calculate a squared value S of the sum of the first amplitude of the transmission signal (first signal) in the phase shift amount (first phase shift amount) of the phase shifter 13 (first phase shifter) obtained from the table data, and the second amplitude of the transmission signal (second signal) in the phase shift amount (second phase shift amount) of the phase shifter 13 (second phase shifter) obtained from the table data; the phase shift amount adjustment unit 103 configured to adjust the phase shift amount (first phase shift amount) and the phase shift amount (second phase shift amount) so as to maximize an evaluation value E obtained by dividing the reception power P by the squared value S. The squared value S represents an expected value expected as the reception power actually obtained by the antenna 21 of the communication device 20 as the reception device, and the evaluation value E is a value obtained by normalizing the reception power P by the squared value S. Therefore, by adjusting the phase shift amount (first phase shift amount) and the phase shift amount (second phase shift amount) so as to maximize the evaluation value E, the phase shift amount (first phase shift amount) and the phase shift amount (second phase shift amount) can be adjusted with high accuracy so that the communication device 20 can obtain the maximum reception power P.

Thus, the phase shift amount adjustment device 100 capable of adjusting the phase shift amount with high accuracy can be provided.

In addition, the table data includes first table data for the phase shifter 13 (first phase shifter) and second table data for the phase shifter 13 (second phase shifter); the first table data represents a first characteristic of the amplitude of the transmission signal (first signal) with respect to the phase shift amount in the phase shifter 13 (first phase shifter), and the second table data represents a second characteristic of the amplitude of the transmission signal (second signal) with respect to the phase shift amount in the phase shifter 13 (second phase shifter). Therefore, the phase shift amount adjustment device 100 capable of adjusting the phase shift amount with high accuracy according to an error, variation, or the like of the amplitude of the transmission signal of each of the multiple phase shifters 13 (first phase shifters) and phase shifters 13 (second phase shifters) can be provided.

In addition, the phase shift amount adjustment unit 103 adjusts the phase shift amount (first phase shift amount) and the phase shift amount (second phase shift amount), and if the evaluation value E obtained by the phase shift amount (first phase shift amount) and the phase shift amount (second phase shift amount) after the adjustment exceeds the evaluation value E obtained by the phase shift amount (first phase shift amount) and the phase shift amount (second phase shift amount) before the adjustment, updates the phase shift amount (first phase shift amount) and the phase shift amount (second phase shift amount) to values after the adjustment. Therefore, while sequentially updating the multiple phase shift amounts (the first phase shift amount and the second phase shift amount), the multiple phase shift amounts (the first phase shift amount and the second phase shift amount) that give the maximum evaluation value E can be obtained.

In the phase shift amount adjustment method, the computer 30 obtains reception power P at the communication device 20 that receives a transmission signal (first signal) and a transmission signal (second signal) from the communication device 10 that has an antenna 14 (first antenna) to transmit a transmission signal (first signal) whose phase shift amount is adjusted by a phase shifter 13 (first phase shifter), and an antenna 14 (second antenna) to transmit a transmission signal (second signal) whose phase shift amount is adjusted by a phase shifter 13 (second phase shifter) ; calculates a squared value S of the sum of the first amplitude of the transmission signal (first signal) in the phase shift amount (first phase shift amount) of the phase shifter 13 (first phase shifter) obtained from the table data, and the second amplitude of the transmission signal (second signal) in the phase shift amount (second phase shift amount) of the phase shifter 13 (second phase shifter) obtained from the table data representing a characteristic of the amplitude of the transmission signal (first signal) with respect to change in the phase shift amount of the phase shifter 13 (first phase shifter), and a characteristic of the amplitude of the transmission signal (second signal) with respect to change in the phase shift amount of the phase shifter 13 (second phase shifter); and adjusts the phase shift amount (first phase shift amount) and the phase shift amount (second phase shift amount) so as to maximize the evaluation value E obtained by dividing the reception power P by the squared value S. Therefore, by adjusting the phase shift amount (first phase shift amount) and the phase shift amount (second phase shift amount) so as to maximize the evaluation value E, the phase shift amount (first phase shift amount) and the phase shift amount (second phase shift amount) can be adjusted with high accuracy so that the communication device 20 can obtain the maximum reception power P.

Therefore, phase shift amount adjustment method capable of adjusting the phase shift amount with high accuracy can be provided.

### Modified Example

Note that in the above, the embodiment has been described in which the table data includes the first table data for one phase shifter 13 (first phase shifter) and the second table data for another phase shifter 13 (second phase shifter). However, the table data may be table data common to the one phase shifter 13 (first phase shifter) and the other phase shifter 13 (second phase shifter). In this case, the table data is table data representing a characteristic of the amplitude of the transmission signal (first signal) and the transmission signal (second signal) with respect to the phase shift amount in the phase shifter 13 (first phase shifter) and the phase shifter 13 (second phase shifter). By using such table data common to the one phase shifter 13 (first phase shifter) and the other phase shifter 13 (second phase shifter), the phase shift amount adjustment device 100 that can operate with a smaller capacity of the memory 104, and can adjust the phase shift amount with high accuracy in a simpler configuration can be provided.

In addition, in the above, although a form in which the phase shifter 13 is connected to each antenna 14 of the communication device 10 has been described, the communication device 10 may have, for example, an antenna 14 to which the phase shifter 13 is not connected. In other words, the communication device 10 may have a configuration that includes an antenna 14 (first antenna) to transmit a transmission signal (first signal) whose phase shift amount is adjusted by a phase shifter 13 (first phase shifter), and an antenna 14 (second antenna) to transmit a transmission signal (second signal) without being connected to a phase shifter 13. In this case, a phase shift amount adjustment device 100 has a configuration that includes: a power obtainment unit 101 configured to obtain reception power P at a communication device 20 that receives a transmission signal (first signal) and a transmission signal (second signal) from a communication device 10 having an antenna 14 (first antenna) to transmit a transmission signal (first signal) whose phase shift amount is adjusted by a phase shifter 13 (first phase shifter), and an antenna 14 (second antenna) to transmit a transmission signal (second signal); a memory 104 configured to store table data representing a characteristic of the amplitude of a transmission signal (first signal) with respect to change in the phase shift amount of the phase shifter 13 (first phase shifter); a calculation unit 102 configured to calculate a squared value S of the sum of the first amplitude of the transmission signal (first signal) and the second amplitude of the transmission signal (second signal) in the phase shift amount (first phase shift amount) of the phase shifter 13 (first phase shifter) obtained from the table data; and a phase shift amount adjustment unit 103 configured to adjust the phase shift amount (first phase shift amount) so as to maximize an evaluation value E obtained by dividing the reception power P by the squared value S.

In the phase shift amount adjustment device 100 having such a configuration, by adjusting the phase shift amount (first phase shift amount) so as to maximize the evaluation value E, the phase shift amount (first phase shift amount) can be adjusted with high accuracy so that the communication device 20 can obtain the maximum reception power P.

Therefore, the phase shift amount adjustment device 100 capable of adjusting the phase shift amount with high accuracy with a simpler configuration can be provided.

Similarly, the phase shift amount adjustment method in the phase shift amount adjustment device 100 has the following configuration. The phase shift amount adjustment method is executed by the computer 30 that obtains the reception power P at the communication device 20 that receives a transmission signal (first signal) and a transmission signal (second signal) from the communication device 10 having the antenna 14 (first antenna) to transmit the transmission signal (first signal) whose phase shift amount is adjusted by a phase shifter 13 (first phase shifter) and the antenna 14 (second antenna) to transmit a transmission signal (second signal); calculates the squared value S of the sum of the first amplitude of the transmission signal (first signal) and the second amplitude of the transmission signal (second signal) in the phase shift amount (first phase shift amount) of the phase shifter 13 (first phase shifter) obtained from the table data representing a characteristic of the amplitude of the transmission signal (first signal) with respect to change in the phase shift amount of the phase shifter 13 (first phase shifter); and adjusts the phase shift amount (first phase shift amount) so as to maximize the evaluation value E obtained by dividing the reception power P by the squared value S.

In the phase shift amount adjustment method having such a configuration, by adjusting the phase shift amount (first phase shift amount) so as to maximize the evaluation value E, the phase shift amount (first phase shift amount) can be adjusted with high accuracy so that the communication device 20 can obtain the maximum reception power P.

Therefore, a phase shift amount adjustment method capable of adjusting a phase shift amount with high with a simpler configuration can be provided.

As above, the phase shift amount adjustment device and the phase shift amount adjustment method of exemplary embodiments in the present disclosure have been described; note that the present disclosure is not limited to the specifically disclosed embodiments, and various changes and modifications may be made without departing from the scope of the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A phase shift amount adjustment device, comprising:
a memory; and
a processor configured to
obtain reception power at a reception device that receives a first signal and a second signal from a transmission device that has a first antenna to transmit the first signal whose phase shift amount is adjusted by a first phase shifter, and a second antenna to transmit the second signal whose phase shift amount is adjusted by a second phase shifter;
store, in the memory, table data representing a characteristic of an amplitude of the first signal with respect to change in the phase shift amount of the first phase shifter, and a characteristic of an amplitude of the second signal with respect to change in the phase shift amount of the second phase shifter;
calculate a squared value of a sum of a first amplitude of the first signal in a first phase shift amount of the first phase shifter obtained from the table data and a second amplitude of the second signal in a second phase shift amount of the second phase shifter obtained from the table data; and
adjust the first phase shift amount and the second phase shift amount so as to maximize an evaluation value obtained by dividing the reception power by the squared value.

2. The phase shift amount adjustment device as claimed in claim 1, wherein the table data is table data common to the first phase shifter and the second phase shifter, the table data representing a characteristic of the amplitudes of the first signal and the second signal with respect to the phase shift amounts in the first phase shifter and the second phase shifter.

3. The phase shift amount adjustment device as claimed in claim 1, wherein the table data includes first table data for the first phase shifter and second table data for the second phase shifter,
wherein the first table data represents a first characteristic of the amplitude of the first signal with respect to the phase shift amount in the first phase shifter, and
wherein the second table data represents a second characteristic of the amplitude of the second signal with respect to the phase shift amount in the second phase shifter.

4. The phase shift amount adjustment device as claimed in claim 1, wherein the processor adjusts the first phase shift amount and the second phase shift amount, and updates the first phase shift amount and the second phase shift amount to values after adjustment in response to the evaluation value obtained by the first phase shift amount and the second phase shift amount after adjustment exceeding the evaluation value obtained by the first phase shift amount and the second phase shift amount before the adjustment.

5. A phase shift amount adjustment device, comprising:
a memory; and
a processor configured to
obtain reception power at a reception device that receives a first signal and a second signal from a transmission device that has a first antenna to transmit the first signal whose phase shift amount is adjusted by a first phase shifter, and a second antenna to transmit the second signal;
store, in the memory, table data representing a characteristic of an amplitude of the first signal with respect to change in the phase shift amount of the first phase shifter;
calculate a squared value of a sum of a first amplitude of the first signal and a second amplitude of the second signal in a first phase shift amount of the first phase shifter obtained from the table data; and
adjust the first phase shift amount so as to maximize an evaluation value obtained by dividing the reception power by the squared value.

6. A phase shift amount adjustment method executed by a computer including a memory and a processor, the phase shift amount adjustment method comprising:
obtaining reception power at a reception device that receives a first signal and a second signal from a transmission device that has a first antenna to transmit the first signal whose phase shift amount is adjusted by a first phase shifter, and a second antenna to transmit the second signal whose phase shift amount is adjusted by a second phase shifter;
calculating a squared value of a sum of a first amplitude of the first signal in a first phase shift amount of the first phase shifter obtained from table data and a second amplitude of the second signal in a second phase shift amount of the second phase shifter obtained from the table data, wherein the table data represents a characteristic of an amplitude of the first signal with respect to change in the phase shift amount of the first phase shifter, and a characteristic of an amplitude of the second signal with respect to change in the phase shift amount of the second phase shifter; and
adjusting the first phase shift amount and the second phase shift amount so as to maximize an evaluation value obtained by dividing the reception power by the squared value.

7. A phase shift amount adjustment method executed by a computer including a memory and a processor, the phase shift amount adjustment method comprising:
obtaining reception power at a reception device that receives a first signal and a second signal from a transmission device that has a first antenna to transmit the first signal whose phase shift amount is adjusted by a first phase shifter, and a second antenna to transmit the second signal;
calculating a squared value of a sum of a first amplitude of the first signal and a second amplitude of the second signal in a first phase shift amount of the first phase shifter obtained from table data, wherein the table data represents a characteristic of an amplitude of the first signal with respect to change in the phase shift amount of the first phase shifter; and
adjusting the first phase shift amount so as to maximize an evaluation value obtained by dividing the reception power by the squared value.
